(19) United States
(12) Patent Application Publication
(10) Pub. No.: US 2008/0203939 A1
(43) Pub. Date: Aug. 28, 2008

(54) Method and Arrangement for Monitoring a Gas Discharge Lamp

(75) Inventors: Pavel Pekarski, Aachen (DE); Carsten Deppe, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/577,427

(22) PCT Filed: Oct. 17, 2005
(86) PCT No.: PCT/IB05/53390

§ 371 Date: Apr. 18, 2007

(30) Foreign Application Priority Data
Oct. 19, 2004 (EP) 04105140.0

(51) Int. Cl. H05B 41/36; G01R 31/00

(52) U.S. Cl. 315/291; 324/414

(57) ABSTRACT

The invention relates to a method and an arrangement (10) for monitoring a gas discharge lamp (22), comprising a control circuit (18) for detecting an electrical measured value assigned to the lamp voltage. The control circuit (18) is provided for detecting one voltage value prior to a change in current and a second voltage value after a change in current, or a setting time, and for producing a control signal which depends on the difference in the voltage values or on the setting time. In this way, a pressure within the lamp is monitored and a control signal can be produced which can be used to cool the lamp or to switch the lamp off. This methods detects inflation and therefore prevents an explosion of the lamp.

The invention relates to a method for monitoring a gas discharge lamp, in which an electrical measured value assigned to the lamp voltage is detected, and also to an arrangement for monitoring a gas discharge lamp, comprising a control circuit for detecting an electrical measured value assigned to the lamp voltage.

Such a method and such an arrangement for monitoring a gas discharge lamp are known from U.S. Pat. No. 6,534,932. The method is said to be used to detect inflation of a lamp tube. When the lamp tube inflates, the pressure within the lamp tube is reduced, and this causes a drop in the lamp voltage. The pressure is essentially determined by mercury evaporated during operation, so that this pressure is also referred to as the mercury vapor pressure or as the mercury pressure for short. A warning signal is output or the lamp is switched off when the voltage drop reaches a predefined value. Unfortunately, practical implementation of the method is fairly problematic since a considerable voltage drop can also be caused by a change in the electrode spacing. In this way, either not all inflations are detected or else fully intact lamps are switched off.

It is therefore an object of the invention to provide a method and a device which can be used to monitor the pressure within the lamp. In particular, inflation of a lamp tube is to be reliably detected.

This object is achieved in accordance with the features of claims 1 to 3 and 5 to 8. According to the invention, the method is characterized by the following method steps: a setting time after a change in current is measured and a control signal is produced as a function of the setting time. The setting time is pressure-dependent. Pressure fluctuations can indicate various causes. Firstly, an air supply to the lamp and thus a cooling of the lamp can be controlled by means of the control signal. The control signal can also be used to delimit a permitted dimming range of the lamp. Moreover, as an essential feature, the control signal can be used to generate a warning which indicates that the lamp has to be replaced and switches the lamp off before it explodes. Inflation of the lamp tube proceeds very slowly. A warning signal can be output with a prior warning time of a few hours.

Under normal operating conditions, the lamp behaves like a voltage source with a negative real part of an impedance and an inductive positive component. The inductive component is predefined by the setting time of the temperature of a plasma which in the operating state is located between electrodes within the lamp tube. The setting time of the plasma is essentially determined by a transmission of energy in the form of light, and thus is highly dependent on the mercury pressure and increases as the pressure decreases. By monitoring the plasma setting time, it is thus possible to monitor and detect a pressure, in particular a pressure drop. A rising or falling edge of a change in current is a trigger for an exponentially decaying voltage peak. The setting time of the plasma is reflected in the exponential voltage course of the lamp and the voltage can be measured directly. The exponential curve becomes flatter as the mercury pressure decreases. The setting time of a new lamp with an operating pressure of 200 bar is around 50 μs, whereas a pressure reduced by a factor of 2 leads to setting times of 200 μs. Inflation of the lamp tube precedes explosion of the lamp. Detecting any inflation of the tube and providing a corresponding warning or switching off the lamp are effective measures for preventing explosion of the lamp. When lamps with or in open reflectors are used in video projectors, in the event of a lamp explosion the glass shatters and damages expensive components which surround it. Moreover, the mercury contaminates the environment around the lamp. For ecological and economic reasons, therefore, it is of great interest to keep the mercury within the lamp tube. In video projectors, use is made of lamps which have become known as ultra-high-pressure gas discharge lamps of the UHP type. The abbreviation UHP stands for Ultra High Pressure or Ultra High Performance. Furthermore, those lamps which are referred to as HID lamps are also used in headlamps in particular of motor vehicles. The abbreviation HID stands for High Intensity Discharge.

The object of the invention is moreover achieved by a method which according to the invention is characterized by the following method steps: a first voltage value is measured prior to a change in current, then a second voltage value is measured after a change in current, and a control signal is produced as a function of a difference in the voltage values. The value of the real part of the impedance of the UHP lamp increases as the mercury vapor pressure decreases. For a pressure in the normal operating state, the impedance has negative values in the range between −2 and −10 Ohm, whereas, as the pressure decreases, the impedance increases to 0 or even to positive values. This change in impedance is reflected in a considerable voltage change which occurs after a change in current. The voltage change can be measured directly. The impedance of the lamp is a function of the pressure and of the electrode spacing, which can be determined experimentally for the respective type of lamp. The associated equation is as follows:

R=f(d,p)

The parameters of this dependence can be determined in a simple manner for each individual type of lamp. The dependence of the lamp voltage on the electrode spacing is likewise known for each individual lamp pressure. The associated equation is as follows:

U(d,p)=const1+const2*p*d

With these known values, it is possible to ascertain whether a voltage change during lamp operation following a change in current is caused by a change in the electrode spacing or by a decrease in the mercury pressure. In this way, inflation of the lamp tube can be detected in its early state.

The object of the invention is moreover achieved by a third method which according to the invention is characterized by the following method steps: one voltage value is measured prior to a change in current and a second voltage value is measured after a change in current and a setting time is also measured, and then a warning signal is produced as a function of the difference in the voltage values and of the setting time. As already mentioned above, a pressure drop causes both a change in the setting time and a change in the voltage following a change in current. Both of these properties are then used to switch off the lamp.

Advantageously, the change in current is caused by a pulse. The setting time following a change in current of a pulse is measured. A rising or falling edge of a current pulse is a trigger for a voltage peak which decays exponentially. The exponential curve becomes flatter as the pressure loss increases. In order to form tips of the electrodes, UHP lamps are operated with a stabilization pulse. Pulsed operation of such a lamp is described in U.S. Pat. No. 6,232,725. When lamps are operated with the stabilization pulse, the differences in lamp voltage between level and pulse can be used directly to measure the real part of the lamp impedance. The increase in impedance to zero or to positive values can be measured as a change in lamp voltage when the current pulse is applied.

It is possible to measure the setting time optionally either on the basis of the rising edge or on the basis of the falling edge of a pulse and the two impedance values before and after either the rising or the falling edge of the pulse. It is furthermore possible to determine the impedance on the basis of a first pulse and the setting time on the basis of a second pulse or vice versa, that is to say to determine the setting time on the basis of a first pulse and the impedance on the basis of a second pulse.

The object of the invention is moreover achieved by an arrangement in which the control circuit is provided for detecting a setting time and for producing a warning signal which depends on the setting time. The control circuit has a microprocessor in which these method steps can be programmed.

The object of the invention is also achieved by a second arrangement in which the control circuit is provided for detecting a first voltage value prior to a change in current and a second voltage value after a change in current, and for producing a warning signal which depends on a difference in the voltage values.

The object of the invention is moreover achieved by a third arrangement in which the control circuit is provided for detecting one voltage value prior to a change in current and a second voltage value after a change in current and also a setting time, and for producing a warning signal which depends on the difference in the voltage values and on the setting time.

The individual method steps can be implemented as a program, referred to as software, in the control circuit.

The invention will be further described with reference to an example of embodiment shown in the drawing to which, however, the invention is not restricted.

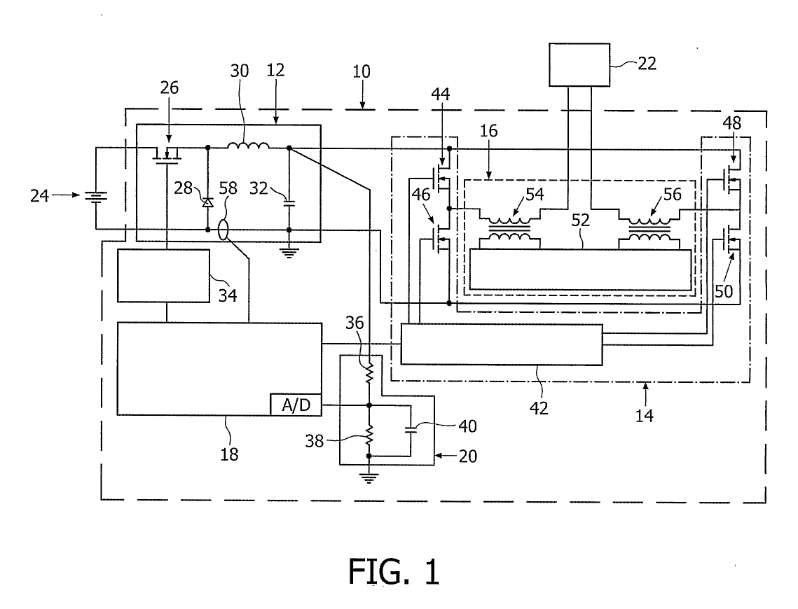

FIG. 1 shows a block diagram with a ballast and with a gas discharge lamp.

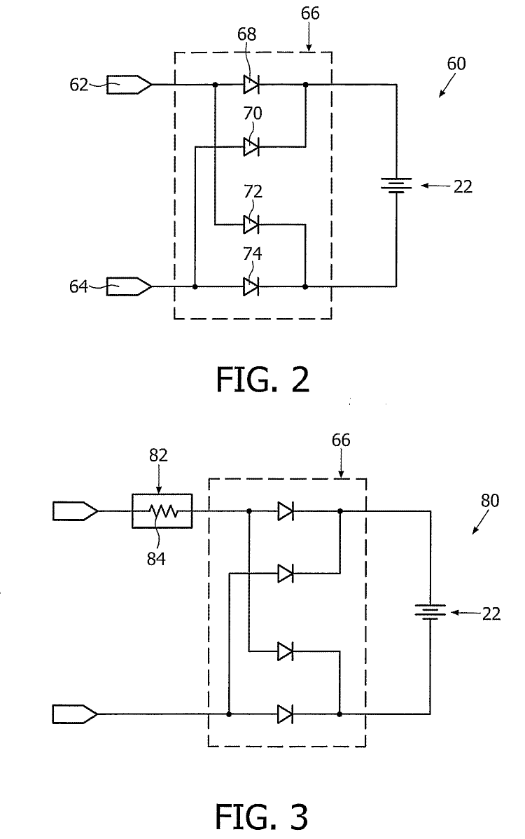

FIG. 2 shows a first equivalent circuit diagram for the gas discharge lamp, in which the commutation is taken into account.

FIG. 3 shows a second equivalent circuit diagram for the gas discharge lamp, in which the commutation and an impedance are taken into account.

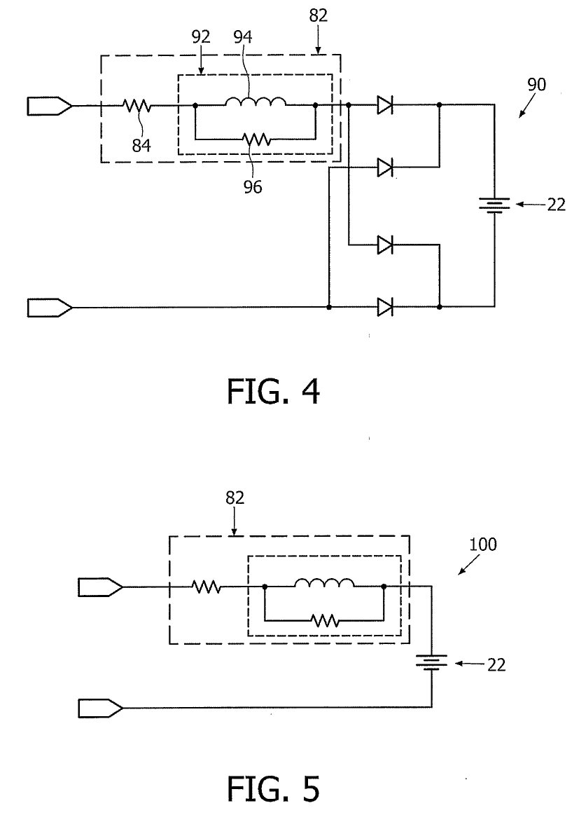

FIG. 4 shows a third equivalent circuit diagram for the gas discharge lamp, in which the commutation, a first, time-independent impedance and a second, time-dependent impedance are taken into account.

FIG. 5 shows a fourth, simplified equivalent circuit diagram for a gas discharge lamp.

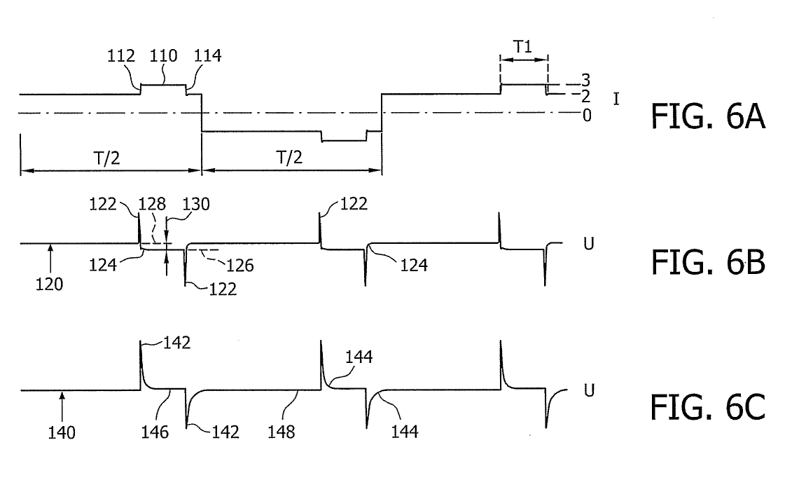

FIG. 6A shows a pulsed current profile on a lamp.

FIG. 6B shows a voltage profile prior to a commutation stage of a lamp.

FIG. 6C shows a second voltage profile prior to a commutation stage of a lamp which is in the process of inflating.

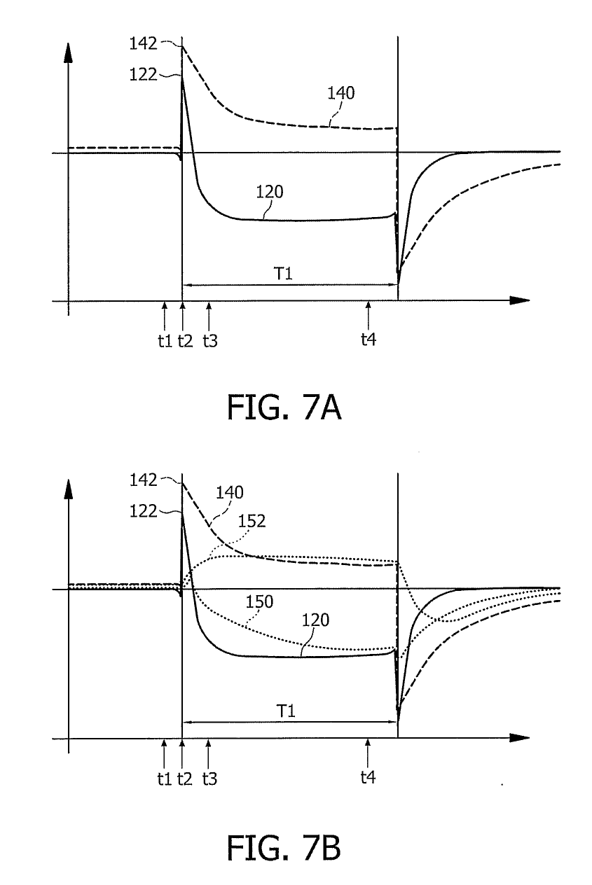

FIG. 7A shows a diagram with a first voltage profile during a pulse in the case of a high pressure and a second voltage profile in the case of a low pressure, with a low time constant of the detector.

FIG. 7B shows a diagram with a first voltage profile during a pulse in the case of a high pressure and a second voltage profile in the case of a low pressure, with a high time constant of the detector.

In the various figures, similar or identical elements bear the same references.

FIG. 1 shows an arrangement 10 comprising a DC converter 12, a commutation stage 14, an ignition device 16, a control circuit 18 and a voltage detector 20. Hereinbelow, the arrangement 10 is also referred to as a ballast or lamp driver. The control circuit 18 controls the converter 12, the commutation stage 14 and the ignition device 16 and monitors the voltage profile of the ballast 10 on a gas discharge lamp 22 by means of the voltage detector 20. The converter 12 is supplied by an external DC power source 24 of for example 380 V. The DC converter 12 has a switch 26, a diode 28, an inductor 30 and a capacitor 32. Via a shifter 34, the control circuit 18 controls the switch 26 and thus the current in the lamp 22. The voltage detector 20 lies parallel to the capacitor 32, said voltage detector being designed as a voltage splitter with two resistors 36 and 38. A capacitor 40 lies parallel to the resistor 38. The commutation stage 14 has a driver 42 which controls four switches 44, 46, 48 and 50. The ignition device 16 has an ignition controller 52 and an ignition transformer, which by means of the two coils 54 and 56 produces a symmetrical high voltage and thus ignites the lamp 22. The control circuit 18 monitors a current by means of a current measurement circuit 58. In order to measure the voltage, a correspondingly reduced voltage is tapped off at the capacitor 32 via the voltage splitter 36, 38 and measured in the control circuit 18 by means of an analog/digital converter. The capacitor 40 serves to reduce high-frequency interference in the measured signal.

FIG. 2 shows a circuit 60 with two terminals 62 and 64, a rectifier 66 consisting of four diodes 68, 70, 72 and 74, and the lamp 22. In a first simple approximation, the electrical behavior of HID and UHP lamps can be described as follows: The gas discharge lamp 22 is to be regarded as a voltage source. The voltage measured on the lamp 22 does not change. The rectifier 66 has to be added in the case of a lamp operated with an AC current. The voltage on the lamp 22 depends on the direction of the current and changes polarity with the current.

FIG. 3 shows a circuit 80 which, in addition to the lamp 22 and the rectifier 66, also has an impedance 82. With more precise measurement, it can be ascertained that the lamp voltage changes to a minimal extent as the current changes. In the case of the UHP lamp 22 with a very high mercury pressure, a lower voltage is obtained as the current increases. This can be described by the impedance 82, which has a resistor 84 with a value of R=−4Ω.

FIG. 4 shows a circuit 90 with the impedance 82. The impedance 82 comprises the resistor 84 and a parallel circuit 92 consisting of an inductor 94 and a further resistor 96. An even more precise measurement then discloses a response process, namely a short peak after a change in current, which decays exponentially. The correct electrical description is the parallel circuit 92 consisting of the inductor 94 and the resistor 96. The resistor 96 describes the level of the peak, and resistor 96 and inductor 94 describe a time constant τ. The impedance 82 is thus a complex and frequency-dependent variable. For the application here, however, the pressure measurement concerns only a negative DC component and the time constant τ of the parallel circuit 92, also referred to as the L/R circuit.

FIG. 5 shows a circuit 100 with the impedance 82 and the lamp 22 without the rectifier 66. The circuit 100 is not valid as a model for the process of reversing the direction of the current, also known as commutation. Since the voltage in the lamp driver 10 is measured before the change in polarity, and thus the effect of the commutation stage 14 of the driver 10 with the rectifier 66 in the lamp model cancel one another out, the rectifier 66 can be omitted.

FIG. 6A shows a current profile as supplied to the lamp 22 by the DC converter 12. Provided at the end of each half-period is a stabilization pulse 110 with a rising and a falling edge 112 and 114. The stabilization pulse 110 has a duration T1.

FIG. 6B shows an associated voltage profile 120 as said voltage drops on an intact lamp. A voltage peak 122 occurs with the rising and falling edges 112 and 114 of the stabilization pulse 110, said voltage peak decaying with a steep exponential voltage curve 124. The setting time of the curve 124 is low and is 50 μs. A voltage level 126 during the stabilization pulse 110 is lower than a voltage level 128 during the rest of the period. A voltage difference 130 between the levels 126 and 128 can be measured.

FIG. 6C shows a voltage profile 140 on the lamp 22 when the lamp tube inflates. A voltage peak 142 occurs with the rising and falling edges 112 and 114 of the stabilization pulse 110, said voltage peak decaying with a flat exponential voltage curve 144. The setting time of the voltage after a rising and falling edge 112 and 114 is greater than that of the intact lamp and is 200 μs. The curve 144 is flatter. A voltage level 146 during the stabilization pulse 110 is more or less the same as the voltage level 128 during the rest of the period.

FIG. 7A shows a diagram with the voltage profile 120 in the case of a high pressure and the voltage profile 140 in the case of a low pressure. The voltage is measured at sampling times t1, t2, t3 and t4. The current pulse with the duration Ti starts shortly before the sampling time t2 and gives rise to a voltage peak 122 or 142 at the time t2. The voltage decays exponentially. The time constant τ and the impedance can be determined on condition that the inductance of the ignition device 16 in front of the lamp 22 is low. The capacitor 40 is of small size, so that the time constant which is formed from the capacitor 40 and the resistors 36 and 38 of the voltage splitter is significantly shorter than the minimum time constant to be measured in the lamp. The voltage signal present at the A/D converter of the control circuit 18 then largely corresponds to the voltage profile 120 or 140 shown in FIG. 7A. Since the control circuit 18 also controls the current and the commutation times, and moreover the current values are known, only the voltage then has to be measured at a number of times t1-t4. Both the time constant and the impedance can then be calculated therefrom. At least 3-4 measurements are required for this purpose, and further sample values increase the accuracy.

FIG. 7B shows a diagram with the voltage profile 120 in the case of a high pressure and the voltage profile 140 in the case of a low pressure. The voltage is measured at sampling times t1 and t4. A current pulse with a duration T1 starts shortly before the sampling time t1 and gives rise to a voltage peak 122 or 142 at the time t2. The voltage decays exponentially.

In this method, a mixed value consisting of impedance and time constant is determined. The capacitor 40 in this case is dimensioned in such a way that the resulting time constant which is formed from the capacitor 40 and the resistors 36 and 38 of the voltage splitter is about the same as the pulse duration T1. As a result, interference is effectively smoothed. In the control circuit 18, a voltage profile 150 in the case of an intact lamp or 152 in the case of a lamp with decreasing pressure is measured by means of the A/D converter. Although a measurement with only two sample values at times t1 and t4 no longer permits a separate analysis of the time constant and of the impedance, since both factors act in the same direction a measured value is obtained which is constant with regard to pressure and can thus be interpreted in an unambiguous manner.

The two alternatives—whether the measurement is carried out with a number of sample values or with just two sample values at times t1-t4—are dependent on the respective design of the driver 10. The first alternative with a number of measured values allows a very precise assessment of the lamp pressure but nevertheless can only be used when the inductances of the ignition device 52 in front of the lamp 22 are low and the DC converter 12 does not cause too much interference. The second alternative allows only a rough measurement but can be carried out in any driver.

An impedance value is calculated from the first and last sample value or in the second alternative from the two sample values by the formula R=ΔU/ΔI=(Uₗₐₛₜ−U_{first})/(Iₚᵤₗₛₑ−Iₚₗₐₜₑₐᵤ), wherein the value Iₚᵤₗₛₑ is the current during the pulse and Iₚₗₐₜₑₐᵤ is the value of the current during the rest of a half-period; as a whole the value for ΔI is known to the controller programming. The time constant can be estimated using sample values 2 to 4. The amplitude can be determined using sample values 2 and 4 and then the time constant can be determined for example by means of sample values 3 and 4.

The most advantageous operating mode for UHP lamps 22 comprises a current pulse 110 before each commutation. This current pulse 110 can be used directly for measurement purposes. Depending on the lamp power, this pulse is between 2 and 10 A for an average current of 1 to 5 A. For a typical lamp power of 120 W, the pulse is at 2.2 to 3 A for a pulse duration of 4 to 8 percent of the half-period, in some cases up to 20 percent of the half-period, and an average current of 1 to 2.5 A. If no pulse 110 is present, it can be used as a test signal with a very low repetition rate, and thus the effect on normal operation is small. Optionally, a positive pulse 110 can be compensated by a negative pulse of equal magnitude in the next lamp current period or directly before or after the positive pulse.

### LIST OF REFERENCES

10 ballast
12 DC converter
14 commutation stage
16 ignition device
18 control circuit
20 voltage detector
22 lamp
24 DC voltage source
26 switch
28 diode
30 inductor
32 capacitor
34 shifter
36 resistor
38 resistor
40 capacitor
42 driver
44 switch
46 switch
48 switch
50 switch
52 ignition controller
54 ignition coil
56 ignition coil
60 switch
62 terminal
64 terminal
66 rectifier
68 diode
70 diode
72 diode
74 diode
80 circuit
82 impedance
84 resistor
90 circuit
92 parallel circuit
94 inductor
96 resistor
100 circuit
110 stabilization pulse
112 rising edge
114 falling edge
120 voltage profile
122 voltage peak
124 exponential voltage curve
126 pulse voltage level
128 period voltage level
130 voltage difference
140 voltage profile
142 voltage peak
144 exponential voltage curve
146 pulse voltage level
150 voltage profile
152 voltage profile

1. A method for monitoring a gas discharge lamp (22), in which an electrical measured value assigned to the lamp voltage is detected, characterized by the following method steps: a setting time after a change in current is measured and a control signal is produced as a function of the setting time.

2. A method for monitoring a gas discharge lamp (22), in which an electrical measured value assigned to the lamp voltage is detected, characterized by the following method steps: a first voltage value is measured prior to a change in current, then a second voltage value is measured after a change in current, and a control signal is produced as a function of a difference (36) in the voltage values.

3. A method for monitoring a gas discharge lamp (22), in which an electrical measured value assigned to the lamp voltage is detected, characterized by the following method steps: one voltage value is measured prior to a change in current and a second voltage value is measured after a change in current and a setting time is also measured, and then a control signal is produced as a function of the difference (36) in the voltage values and of the setting time.

4. A method as claimed in claim 1, characterized in that the change in current is caused by a pulse (30).

5. An arrangement (10) for monitoring a gas discharge lamp (22), comprising a control circuit (18) for detecting an electrical measured value assigned to the lamp voltage, characterized in that the control circuit (18) is provided for detecting a setting time and for producing a control signal which depends on the setting time.

6. An arrangement (10) for monitoring a gas discharge lamp (22), comprising a control circuit (18) for detecting an electrical measured value assigned to the lamp voltage, characterized in that the control circuit (18) is provided for detecting a first voltage value prior to a change in current and a second voltage value after a change in current, and for producing a control signal which depends on a difference (36) in the voltage values.

7. An arrangement (10) for monitoring a gas discharge lamp (22), comprising a control circuit (18) for detecting an electrical measured value assigned to the lamp voltage, characterized in that the control circuit (18) is provided for detecting one voltage value prior to a change in current and a second voltage value after a change in current and also a setting time, and for producing a control signal which depends on the difference (36) in the voltage values and on the setting time.

8. A program for a method as claimed in claim 1.

9. A video projector in which a method as claimed in claim 1 can be used.

10. A video projector comprising an arrangement (10) for monitoring a gas discharge lamp (22) as claimed in claim 1.
